(19) United States
(12) Patent Application Publication
(10) Pub. No.: US 2026/0009159 A1
(43) Pub. Date: Jan. 8, 2026

(54) AlN SINGLE CRYSTAL SUBSTRATE AND DEVICE

(71) Applicant: NGK INSULATORS, LTD., Nagoya-shi (JP)

(72) Inventors: Kyohei ATSUJI, Nagoya-shi (JP); Hiroharu KOBAYASHI, Kasugai-shi (JP); Eri KAWAGUCHI, Nagoya-shi (JP); Katsuyuki TAKEUCHI, Aisai-shi (JP)

(21) Appl. No.: 19/328,402

(22) Filed: Sep. 15, 2025

Related U.S. Application Data
(63) Continuation of application No. PCT/JP2023/010475, filed on Mar. 16, 2023.

(51) Int. Cl. C30B 29/40; C30B 23/02; C30B 23/06; C30B 35/00

(52) U.S. Cl. CPC C30B 29/403; C30B 23/066; C30B 23/025; C30B 35/002

(57) ABSTRACT

There is provided an AlN monocrystalline substrate having a size with a diameter of 5.08 cm (2 inch) or more and having a two-layer structure composed of a single AlN monocrystalline as a whole, the two-layer structure composed of a first layer and a second layer distinguishable from each other in a thickness direction regarding a full width at half maximum of an XRC. A full width at half maximum of an XRC of a (002) plane of the first layer is 0.005° or more and less than 0.160°; a full width at half maximum of an XRC of a (002) plane of the second layer is 0.03° or more and 0.16° or less; and a ratio of the full width at half maximum of an XRC of a (002) plane of the first layer to that of a (002) plane of the second layer is 0.03 to 0.99.

### CROSS-REFERENCE TO RELATED APPLICATION

This application is a continuation application of PCT/JP2023/010475 filed Mar. 16, 2023, the entire contents all of which are incorporated herein by reference.

### BACKGROUND OF THE INVENTION

### 1. Field of the Invention

The present invention relates to an AlN monocrystalline substrate and a device including the AlN monocrystalline substrate.

### 2. Description of the Related Art

Aluminum nitride (AlN) monocrystalline attracts attention as a base substrate of a deep ultraviolet light-emitting device including an AlN-based semiconductor. For example, AlN or AlGaN is used as an AlN-based semiconductor. These AlN-based semiconductors, which have a band structure of direct transition type, are suitable for a light-emitting device and can be applied to deep ultraviolet LEDs (Light Emitting Diodes) and deep ultraviolet LDs (Laser Diodes), which can be used for applications including sterilization.

In light of achieving high luminous efficiency in such light-emitting devices, there is a need for high quality base substrates that have high crystallinity and therefore improved thermal conductivity and also have fewer defects including cracks.

Thus, AlN substrates having high crystallinity have been developed as base substrates. Patent Literature 1 (JP6872074B) discloses an AlN substrate satisfying relational inequations: c1>97.5% and c2/c1<0.995, wherein c1 represents a degree of c-plane orientation that is a proportion of the diffraction intensity of the (002) plane to the sum of the diffraction intensity of the (002) plane and the diffraction intensity of the (100) plane, as X-ray diffractometry is performed in the thickness direction on the surface layer, and c2 represents a degree of c-plane orientation that is a proportion of the diffraction intensity of the (002) plane to the sum of the diffraction intensity of the (002) plane and the diffraction intensity of the (100) plane, as X-ray diffractometry is performed in the thickness direction on a portion other than the surface layer. Patent Literature 2 (JP6872075B) discloses an AlN substrate satisfying relational inequations: c1>97.5% and c2>97.0%, wherein c1 and c2 are as defined above, and wherein the AlN substrate also satisfies relational inequations: w1<2.5° and w1/w2<0.995, wherein w1 represents a full width at half maximum of an X-ray rocking curve profile of a (102) plane of a surface layer and w2 represents a full width at half maximum of an X-ray rocking curve profile of a (102) plane of a portion other than the surface layer.

AlN substrates with a smaller defect density have also been developed as base substrates. Patent Literature 3 (JP2017-117972A) discloses an AlN monocrystalline laminate having a top surface and a bottom surface, wherein the top surface and the bottom surface are both Al polar surfaces and have a dislocation density of 10⁶ cm⁻² or less. This AlN monocrystalline laminate is produced by providing an AlN monocrystalline substrate produced by a sublimation method and forming an AlN monocrystalline layer on the N polar surface of the AlN monocrystalline substrate by a HVPE method (Hydride Vapor Phase Epitaxy method). Here, many defects means many dislocations.

Furthermore, AlN substrates that are resistant to cracking have also been developed as base substrates. Patent Literature 4 (WO2022/201986A1) discloses an AlN monocrystalline substrate, wherein the inside thereof has a larger defect density than those of the top surface and the bottom face thereof.

### CITATION LIST

### Patent Literature

Patent Literature 1: JP6872074B
Patent Literature 2: JP6872075B
Patent Literature 3: JP2017-117972A
Patent Literature 4: WO2022/201986A1

### SUMMARY OF THE INVENTION

In Patent Literatures 1 and 2, there are however no disclosure of specific numerical values relating to crystallinity, and the AlN substrates as disclosed in these Patent Literatures each have a full width at half maximum as large as about 2.5, which means poor crystallinity. Furthermore, these AlN substrates each are polycrystalline, which includes grain boundary, and thus thermal resistance is present therein. In light of this, it is expected that these AlN substrates are poor in thermal conductivity. Although there is no direct mention, it is also expected that these AlN substrates have a large dielectric loss due to the poor crystallinity thereof. Thus, these AlN substrates are considered to provide a large signal loss when used for communication devices and the like. It is expected that AlN substrates as disclosed in Patent Literature 3 have a uniform dislocation density throughout the whole AlN monocrystalline, and these are thus considered to be prone to cracking. AlN substrates as disclosed in Patent Literature 4, which have a trilayer structure composed of a top layer, an intermediate layer, and a bottom layer in view of a defect density, need many process steps and are therefore high-cost. In addition, a sample may have an increased residual stress, and the AlN substrate may be broken when processed in downstream steps. Furthermore, it is expected that in a case where a layer having a smaller defect density is thicker than another layer, cracking is not suppressed when dislocation is developed. In addition, it is expected that the risk of breakage increases further when an AlN substrate has a large diameter. The “downstream steps” herein generally include the steps of slicing, cutting, dicing, grinding, and polishing a surface to be used for epitaxial growth of semiconductor film for a deep ultraviolet light-emitting device so as to obtain a desired semiconductor film, and the step of fabricating a deep ultraviolet light-emitting device actually. Thus, there is a need for an AlN substrate that has improved thermal conductivity due to high crystallinity and is also resistant to cracking otherwise caused by processing.

The inventors have found that an AlN monocrystalline substrate having a two-layer structure composed of a single AlN monocrystalline as a whole and having controlled full widths at half maximum of X-ray rocking curves has high crystallinity and therefore improved thermal conductivity and is also resistant to cracking otherwise caused by processing (including grinding, polishing, and cutting) the AlN monocrystalline substrate.

Thus, an object of the present invention is to provide an AlN monocrystalline substrate that has improved thermal conductivity due to high crystallinity and is also resistant to cracking otherwise caused by processing (including grinding, polishing, and cutting).

The present invention provides the following aspects:

### [Aspect 1]

An AlN monocrystalline substrate having a size with a diameter of 5.08 cm (2 inch) or more, wherein the AlN monocrystalline substrate has a two-layer structure composed of a single AlN monocrystalline as a whole, the two-layer structure composed of a first layer and a second layer distinguishable from each other in a thickness direction in terms of a full width at half maximum of an X-ray rocking curve,
wherein a full width at half maximum of an X-ray rocking curve of a (002) plane of the first layer is 0.005° or more and less than 0.160°,
wherein a full width at half maximum of an X-ray rocking curve of a (002) plane of the second layer is 0.03° or more and 0.16° or less, and
wherein a ratio of the full width at half maximum of an X-ray rocking curve of a (002) plane of the first layer to the full width at half maximum of an X-ray rocking curve of a (002) plane of the second layer is 0.03 to 0.99.

### [Aspect 2]

The AlN monocrystalline substrate according to aspect 1, wherein the first layer has a thermal conductivity of 150 to 210 W/mK.

### [Aspect 3]

The AlN monocrystalline substrate according to aspect 1 or 2, wherein the second layer has a thermal conductivity of 130 to 200 W/mK.

### [Aspect 4]

The AlN monocrystalline substrate according to any one of aspects 1 to 3, wherein a ratio of a thermal conductivity of the first layer to a thermal conductivity of the second layer is 1.00 to 1.50.

### [Aspect 5]

The AlN monocrystalline substrate according to any one of aspects 1 to 4, wherein the first layer has a defect density of 4.5×10⁴ to 1.1×10⁶/cm².

### [Aspect 6]

The AlN monocrystalline substrate according to any one of aspects 1 to 5, wherein the second layer has a defect density of 2.0×10⁵ to 1.2×10⁶/cm².

### [Aspect 7]

The AlN monocrystalline substrate according to any one of aspects 1 to 6, wherein a ratio of a defect density of the first layer to a defect density of the second layer is 0.03 or more and less than 1.00.

### [Aspect 8]

A device comprising the AlN monocrystalline substrate according to any one of aspects 1 to 7.

### BRIEF DESCRIPTION OF DRAWING

FIG. 1 is a schematic cross section showing the configuration a film deposition equipment used for sublimation method.

### DETAILED DESCRIPTION OF THE INVENTION

### AlN Monocrystalline Substrate

The AlN monocrystalline substrate according to the present invention has a size with a diameter of 5.08 cm (2 inch) or more. The AlN monocrystalline substrate is an AlN monocrystalline substrate having two-layer structure composed of a single AlN monocrystalline as a whole, the two-layer structure composed of a first layer and a second layer distinguishable from each other in a thickness direction in terms of a full width at half maximum of an X-ray rocking curve. The full width at half maximum of an X-ray rocking curve of a (002) plane of the first layer is 0.005° or more and less than 0.160°. The full width at half maximum of an X-ray rocking curve of a (002) plane of the second layer is 0.03° or more and 0.16° or less. The ratio of the full width at half maximum of an X-ray rocking curve of a (002) plane of the first layer to the full width at half maximum of an X-ray rocking curve of a (002) plane of the second layer is 0.03 to 0.99. The AlN monocrystalline substrate having a two-layer structure composed of a single AlN monocrystalline as a whole and having controlled full widths at half maximum of X-ray rocking curves as described above has improved thermal conductivity due to high crystallinity and is also resistant to cracking otherwise caused by processing (including grinding, polishing, and cutting). Accordingly, when such an AlN monocrystalline substrate is processed, an AlN monocrystalline substrate can be produced with high yield. In addition, a deep ultraviolet light-emitting device obtained by using such an AlN monocrystalline substrate has fewer defects in the surface of the substrate, and accordingly, the yield and luminous efficiency of the devices can be improved.

As described above, conventional AlN monocrystalline substrates, which are poor in crystallinity, have small thermal conductivity, and also have a problem of easily causing a crack. In that respect, the AlN monocrystalline substrate according to the present invention can conveniently solve the above-described problems. Particularly, it is expected that the AlN substrates as disclosed in Patent Literatures 1 and 2 are poor in crystallinity and thus poor in thermal conductivity. In contrast, the AlN monocrystalline substrate according to the present invention, which has a small full width at half maximum of an X-ray rocking curve of a (002) plane, has improved crystallinity to improve the thermal conductivity and also has improved dielectric loss. It is expected that the AlN substrate as disclosed in Patent Literature 3 is prone to cracking and has high risk of breakage. In contrast, in the AlN monocrystalline substrate according to the present invention, which has a two-layer structure composed of the first layer and the second layer (preferably the second layer has a larger defect density than that of the first layer), development of crack propagation to the surface of the substrate ceases and occurrence of a crack or breakage can thus be suppressed. There is a possibility, for example, that the AlN substrate as described in Patent Literature 4 is broken when processed in a downstream step. In contrast, the AlN monocrystalline substrate according to the present invention, which has a two-layer structure composed of the first layer and the second layer, can achieve decrease in the number of the steps in the production of the substrate to reduce the cost. In addition, the AlN monocrystalline substrate according to the present invention, which has a simple structure composed of two layers, leads to decrease in the residual stress in the substrate so that the risk of breakage of the substrate is also reduced. Furthermore, in a preferable case where the ratio of the defect density of the first layer to the defect density of the second layer is less than 1.00, the AlN monocrystalline substrate according to the present invention can be effectively resistant to cracking when the substrate has a large diameter.

Herein, the AlN monocrystalline substrate having “a two-layer structure composed of a single AlN monocrystalline as a whole, the two-layer structure composed of a first layer and a second layer distinguishable from each other in a thickness direction in terms of a full width at half maximum of an X-ray rocking curve” refers to an AlN monocrystalline substrate that is composed of two layers conveniently or conceptually distinguishable from each other, i.e., a first layer and a second layer, (these may be referred to as two layer regions, a first region and a second region, if necessary) in terms of the degree of a full width at half maximum of an X-ray rocking curve determined by a known method though it is a monocrystalline that is difficult to find to be divided into two layers by observation of its cross section. In addition, the AlN monocrystalline substrate refers to an AlN monocrystalline substrate that is composed of two layers distinguishable from each other according to the level of a full width at half maximum of an X-ray rocking curve in the above-described way and also configured such that the two layers can be collectively identified as a single monocrystalline without grain boundary between the layers. Here, the AlN monocrystalline substrate can be analyzed in the following manner to distinguish two layers from each other according to the level of a full width at half maximum of an X-ray rocking curve. For example, XRC determination can be carried out to determine the full width at half maximum of the X-ray rocking curve in the thickness direction of an AlN monocrystalline substrate to distinguish the first layer and the second layer from each other. A specific method is as follows: the full width at half maximum of the X-ray rocking curve is determined on the surface of the AlN monocrystalline substrate; the monocrystalline substrate is then polished by a given thickness (for example, one-tenth of the thickness of the monocrystalline substrate, or 30 μm), and the full width at half maximum of the X-ray rocking curve is determined on the surface appearing by the polishing; this operation was repeated every given thickness polishing to thereby obtain a distribution, in the thickness direction, of the full width at half maximum of the X-ray rocking curve; then, the plane inside the AlN monocrystalline substrate is identified that provides the maximum full width at half maximum of the X-ray rocking curve; next, the region was identified as the first layer, the region corresponding to a full width at half maximum of 0.03 to 0.99 times as large as the maximum full width at half maximum of the X-ray rocking curve, wherein the full width at half maximum is 0.005° or more and less than 0.160°, to thereby identify the border between the first layer and the second layer. On the AlN monocrystalline substrate according to the present invention, the maximum full width at half maximum of the X-ray rocking curve of the (002) plane of each layer is determined, and this enables distinction between the first layer and the second layer of the AlN monocrystalline substrate. On this occasion, the average of the full width at half maximum of the X-ray rocking curve of the (002) plane determined in the first layer region is used as the full width at half maximum of the X-ray rocking curve of the (002) plane of the first layer, and also the average of the full width at half maximum of the X-ray rocking curve of the (002) plane determined in the second layer region is used as the full width at half maximum of the X-ray rocking curve of the (002) plane of the second layer.

The AlN monocrystalline substrate according to the present invention is resistant to cracking, even when it has a large diameter. Accordingly, the AlN monocrystalline substrate has a size with a diameter of 5.08 cm (2 inch) or more, and typically has a size with a diameter of 5.08 to 11.0 cm.

The full width at half maximum of the X-ray rocking curve of a (002) plane of the first layer of the AlN monocrystalline substrate is 0.005° or more and less than 0.160°, preferably 0.005° to 0.120°, more preferably 0.005° to 0.100°, even more preferably 0.005° to 0.008°. On the other hand, the full width at half maximum of the X-ray rocking curve of a (002) plane of the second layer is 0.03° or more and 0.16° or less, preferably 0.03° to 0.10°, more preferably 0.03° to 0.08°, even more preferably 0.03° to 0.05°. The full width at half maximum of the X-ray rocking curve of a (002) plane of the first layer is smaller than the full width at half maximum of the X-ray rocking curve of a (002) plane of the second layer, and this can provide an AlN monocrystalline substrate that has improved thermal conductivity due to high crystallinity and is also resistant to cracking otherwise caused by processing (including grinding, polishing, and cutting). In view of this, the ratio of the full width at half maximum of the X-ray rocking curve of a (002) plane of the first layer to the full width at half maximum of the X-ray rocking curve of a (002) plane of the second layer is 0.03 to 0.99, preferably 0.03 to 0.95, more preferably 0.03 to 0.50, even more preferably 0.03 to 0.25.

The first layer of the AlN monocrystalline substrate preferably has a thermal conductivity of 150 to 210 W/mK, more preferably 170 to 210 W/mK, even more preferably has 190 to 210 W/mK. On the other hand, the second layer preferably has a thermal conductivity of 130 to 200 W/mK, more preferably 170 to 200 W/mK, even more preferably has 190 to 200 W/mK. The thermal conductivity of the first layer is preferably equal to or larger than that of the second layer, and this can more effectively provide an AlN monocrystalline substrate that has improved thermal conductivity due to high crystallinity and is also resistant to cracking otherwise caused by processing (including grinding, polishing, and cutting). In view of this, the ratio of the thermal conductivity of the first layer to that of the second layer is preferably 1.00 to 1.50, more preferably 1.20 to 1.50, even more preferably 1.30 to 1.50.

The first layer of the AlN monocrystalline substrate preferably has a defect density of 4.5×10⁴ to 1.1×10⁶/cm², more preferably 4.5×10⁴ to 5.0×10⁵/cm², even more preferably 4.5×10⁴ to 1.0×10⁵/cm². On the other hand, the second layer preferably has a defect density of 2.0×10⁵ to 1.2×10⁶/cm², more preferably 2.0×10⁵ to 8.0×10⁵/cm², even more preferably 2.0×10⁵ to 6.0×10⁵/cm². The defect density of the first layer is preferably smaller than that of the second layer, and this can more effectively provide an AlN monocrystalline substrate that has improved thermal conductivity due to high crystallinity and is also resistant to cracking otherwise caused by processing (including grinding, polishing, and cutting). In view of this, the ratio of the defect density of the first layer to that of the second layer is preferably 0.03 or more and less than 1.00, more preferably 0.03 to 0.50, even more preferably 0.03 to 0.25.

The first layer and the second layer composing the AlN monocrystalline substrate form a single AlN monocrystalline as a whole, and can be said to be orientated layers. In the present invention, an AlN monocrystalline refers to an AlN monocrystalline that is oriented to both the c axis direction and the a axis direction, and encompasses a mosaic crystal. The mosaic crystal refers to a gathering of crystals that have no clear grain boundary but have crystal orientations slightly different from one or both of the c axis direction and the a axis direction. Such an orientated layer has a structure in which the crystal orientations are generally coincident with the almost normal direction (the c axis direction) and the in-planar direction (the a axis direction). Due to such a structure, a semiconductor layer with excellent quality, particularly, excellent orientation, can be formed thereon. Namely, when a semiconductor layer is formed on the orientated layer, the crystal orientations of the semiconductor layer generally follow the crystal orientations of the orientated layer. Thus, an oriented film can be formed as a semiconductor film on the AlN monocrystalline substrate.

In the first layer and the second layer, AlN crystal is oriented to both to the c axis direction and the a axis direction. The method for evaluating the orientation is not particularly limited, and a known analytical method can be used, including EBSD (Electron Back Scatter Diffraction Patterns) method and a method involving use of a X-ray pole figure. For example, when the EBSD method is used, an inverse pole figure mapping and a crystal orientation mapping are determined on a surface (planar surface) of an AlN monocrystalline layer or a cross section perpendicular to the planar surface. It can be determined that the AlN crystal is oriented to two directions, i.e., the almost normal direction and the almost planar direction, if the following four conditions are satisfied: in the resulting inverse pole figure mapping, (A) the AlN crystal is oriented in the specific orientation in the almost normal direction of the planar surface (a first axis), and (B) the AlN crystal is oriented in the specific orientation in almost in-planar direction perpendicular to the first axis (a second axis); and in the resulting crystal orientation mapping, (C) the angles inclining from the first axis are distributed within ±10°, and (D) the angles inclining from the second axis are distributed within ±10°. In other words, it can be determined that the AlN crystal is oriented to two axes, the c axis and the a axis, if the above-described four conditions are satisfied. For example, in a case where the almost normal direction to the planar surface is oriented to the c axis, the almost in-planar direction may be oriented to the specific orientation perpendicular to the c axis (e.g., the a axis). The AlN monocrystalline may be oriented to two axes, the almost normal direction and the almost in-planar direction, and the almost normal direction is preferably oriented to the c axis. As the distribution of the inclination angle(s) in the almost normal direction and/or the almost in-planar direction is smaller, the AlN monocrystalline is less mosaic, and as the distribution is closer to zero, the AlN monocrystalline is closer to perfect monocrystalline. Thus, the distribution of the inclination angle is preferably smaller in both the almost normal direction and the almost planar direction, in view of the crystallinity of the AlN monocrystalline, and the distribution of the inclination angle is preferably ±5° or less, and more preferably ±3° or less, for example.

### Production Method

The AlN monocrystalline substrate of the present invention can be produced by any of various methods, as long as the resulting substrate has a two-layer structure composed of a single AlN monocrystalline as a whole, wherein the full width at half maximum of X-ray rocking curve of a (002) plane of the first layer is 0.005° or more and less than 0.160°, the full width at half maximum of X-ray rocking curve of a (002) plane of the second layer is 0.03° or more and 0.16° or less, and the ratio of the full width at half maximum of X-ray rocking curve of a (002) plane of the first layer to the full width at half maximum of X-ray rocking curve of a (002) plane of the second layer is 0.03 to 0.99. A seed substrate may be provided, on which an AlN monocrystalline substrate is epitaxially formed, or an AlN monocrystalline substrate may be directly produced by formation of spontaneous nucleation without use of a seed substrate. As the seed substrate, an AlN substrate may be used to cause homoepitaxial growth, or another substrate may be used to cause heteroepitaxial growth. For the growth of monocrystalline, any of a vapor phase deposition method, a liquid phase deposition method, and a solid phase deposition method may be used. Preferably, an AlN monocrystalline is formed by a vapor phase deposition method, followed by grinding to remove the seed substrate portion, as necessary, to thereby obtain an intended AlN monocrystalline substrate. Examples of the vapor phase deposition method includes various CVD (chemical vapor deposition) methods (e.g., thermal CVD method, plasma CVD method, MOVPE method, etc.), sputtering method, hydride vapor phase epitaxy (HVPE) method, molecular beam epitaxy (MBE) method, sublimation method, and pulsed laser deposition (PLD) method, and the sublimation method or the HVPE method is preferred. Examples of the liquid phase deposition method include solution growth method (e.g., flux method). The AlN monocrystalline substrate can be obtained through the step of forming an oriented precursor layer, the step of heat-treating the oriented precursor layer to give an AlN monocrystalline layer, and the step of grinding to remove the seed substrate, instead of forming AlN monocrystalline directly on a seed substrate. On this occasion, the method for forming the oriented precursor layer may be an AD (aerosol deposition) method or a HPPD (supersonic plasma particle deposition) method.

In any process of the solid phase deposition method, the vapor phase deposition method, and the liquid phase deposition method described above, known conditions can be used. As an example, a process for preparing an AlN monocrystalline substrate by sublimation method will be described below. Specifically, an AlN monocrystalline substrate is prepared by (a) preparation of the second layer, (b) grinding to remove the seed substrate and polishing the surface of the second layer, (c) preparation of the first layer, and (d) polishing the surface of the first layer.

### (a) Preparation of Second Layer

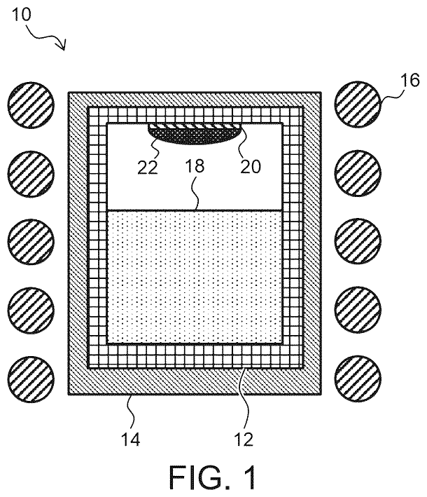

This step is of forming an AlN monocrystalline on a seed substrate in a device for growing crystalline. An example of the device for growing crystalline used for the sublimation method is shown in FIG. 1. The film deposition equipment 10 shown in FIG. 1 includes a crucible 12, a heat insulating material 14 for insulating the crucible 12, and a coil 16 for heating the crucible 12 to high temperature. The crucible 12 contains an AlN raw material powder 18 at its bottom, and has, at its top, a seed substrate 20 for depositing the sublimated product of the AlN raw material powder 18. Pressure is applied to the inside of the crucible 12 in N₂ atmosphere, and the crucible 12 is heated with the coil 16 to sublimate the AlN raw material powder 18. The pressure is preferably 10 to 100 kPa, and more preferably 20 to 90 kPa. On this occasion, a temperature gradient is applied so that the temperature near the seed substrate 20 at the top of the crucible 12 is lower than the temperature near the AlN raw material powder 18 at the bottom of the crucible 12. For example, it is preferable to heat the portion near the AlN raw material powder 18 in the crucible 12 to 1900 to 2250° C., more preferably to 2000 to 2200° C., and it is preferable to heat the portion near the seed substrate 20 of the crucible 12 to 1400 to 2150° C., more preferably to 1500 to 2050° C. At this time, it is preferable that the temperature of the portion near the seed substrate 20 should be lower than the temperature of the portion near the AlN raw material powder 18 by 100 to 500° C., and more preferably by 200 to 400° C. The heating is preferably maintained for 2 to 100 hours, and more preferably for 4 to 90 hours. Temperature control can be performed by measuring the temperature of the top and bottom portions of the crucible 12 using a radiation thermometer (not shown) through a hole in the heat insulating material 14 covering the crucible 12 and providing feedback to the temperature regulation. In this manner, SiC monocrystalline, for example, can be placed as the seed substrate 20, and AlN can be re-deposited on its surface to form an AlN monocrystalline layer 22 (the second layer).

### (b) Grinding to Remove Seed Substrate and Polishing Surface of Second Layer

This step includes the substep of grinding to remove the seed substrate to thereby expose the second layer and the substep of polishing the surface of the second layer to eliminate irregularities and defects thereof. In the second layer prepared through the above-described step (a) using a SiC substrate as the seed substrate, SiC monocrystalline remains, and accordingly, the second layer is subjected to the grinding to expose the surface of the second layer. In addition, to achieve a mirror finish on the surface of the second layer formed, the planar surface is smoothed by lapping with diamond abrasive grains, and then subjected to polishing, for example, chemical mechanical polishing (CMP) with colloidal silica or the like. In this manner, the second layer for a substrate can be prepared.

### (c) Preparation of First Layer

This step is of forming AlN monocrystalline on the second layer in a device for growing crystalline. The first layer can be formed on the second layer in the same manner as for the step (a) described above, except that the second layer for a substrate is used as a seed substrate to form an AlN monocrystalline layer.

### (d) Polishing Surface of First Layer

This step includes the substep of polishing the surface of the first layer to eliminate irregularities and defects thereof. To achieve a mirror finish on the surface of the first layer prepared through the above-described step (c) using the second layer as a seed substrate, the planar surface is smoothed by lapping with diamond abrasive grains, and then subjected to polishing, for example, chemical mechanical polishing (CMP) with colloidal silica or the like. In this manner, an AlN monocrystalline substrate can be prepared that has a two-layer structure composed of a first layer and a second layer distinguishable from each other.

### Device

The AlN monocrystalline substrate according to the present invention can be used to prepare a device. In other words, a device is preferably provided that includes the AlN monocrystalline substrate. Examples of the device include a deep ultraviolet laser diode, a deep ultraviolet diode, a power electronic device, a high frequency device, and a heat sink. The method for producing the device including an AlN monocrystalline substrate is not particularly limited, and the device can be produced by a known process.

### EXAMPLES

The present invention will be further specifically described by way of examples below.

### Examples 1 to 17

### (1) Preparation of AlN Monocrystalline Substrate

### (1a) Preparation of Second Layer

A crucible was used as a container for growing crystalline. In the crucible, a SiC substrate (diameter 5.08 cm) was set as the base material, and an AlN raw material powder was placed therein such that the SiC substrate did not come into contact with the powder. Pressure was applied to the container for growing crystalline at 50 kPa in N₂ atmosphere. The portion near the AlN raw material powder in the container for growing crystalline was heated to 2100° C. by high-frequency induction heating, while the portion near the SiC substrate in the container for growing crystalline was heated to a lower temperature than the above (temperature difference ΔT=200° C.), and the heating was maintained to thereby re-deposited AlN on the SiC substrate. The maintaining time was 10 to 40 hours. The SiC substrate on which AlN had re-deposited was ground using a grindstone with a grain size up to #2000, until the AlN monocrystalline was exposed. Then, the planar surface was further smoothed by lapping with diamond abrasive grains. Thereafter, the surface was subjected to chemical mechanical polishing (CMP) with colloidal silica to achieve a mirror finish. In this manner, AlN monocrystalline (the second layer) was prepared. Then, the surface of the AlN monocrystalline that had been in contact with SiC was regarded as the bottom surface, and the surface opposite from the bottom surface was regarded as the top surface. EBSD determination was carried out on the top surface and the bottom surface of this AlN monocrystalline, and as a result, the AlN crystal was oriented to both the c axis direction and the a axis direction.

### (1 b) Preparation of First Layer

A crucible was used as a container for growing crystalline. In the crucible, the AlN monocrystalline obtained in (1a) above (the second layer) was set as the base material, and an AlN raw material powder was placed in the container such that the second layer did not come into contact with the powder. The AlN monocrystalline was set such that the top surface thereof was exposed to the AlN raw material powder. Pressure was applied to the container for growing crystalline at 50 kPa in N₂ atmosphere. The portion near the AlN raw material powder in the container for growing crystalline was heated to 2100° C. by high-frequency induction heating, while the portion near the AlN monocrystalline in the container for growing crystalline was heated to a lower temperature than the above (temperature difference ΔT=200° C.), and the heating was maintained for 10 to 40 hours to thereby form a first layer on the surface of the AlN monocrystalline. The surface of the first layer was ground to remove a given mass and polished to a desired thickness. In this manner, a circular AlN monocrystalline substrate was prepared that had a two-layer structure composed of a single AlN monocrystalline as a whole, the two-layer structure composed of a first layer and a second layer distinguishable from each other in a thickness direction in terms of a full width at half maximum of an X-ray rocking curve. The AlN monocrystalline substrate had a circular shape in a size with a diameter of 5.08 cm (2 inch).

### (2) Evaluation of AlN Monocrystalline Substrate

### (2a) Full Width at Half Maximum of X-Ray Rocking Curve

XRC determination was carried out on the (002) plane of the first layer and that of the second layer of the AlN monocrystalline substrate using a multi-functional high-resolution X-ray diffractometer (manufactured by Bruker AXS, D8 DISCOVER). The conditions for the XRC determination were as follows.

### <Conditions for XRC Determination>

Tube voltage: 40 kV
Tube current: 40 mA
Detector: Tripple Ge(220) Analyzer
CuKα radiation parallel-monochromatized (full width at half maximum 28 seconds) using a Ge (022) monochromator of asymmetric reflection-type
Step width: 0.001°
Scan speed: 0.5 seconds/step

In the actual determination procedure in Examples 1 to 15, the average of the full width at half maximum of the X-ray rocking curve was determined on the (002) plane of the first layer within a region of 20 to 100 μm away from the first layer surface in the thickness direction, and the resulting average was used as the full width at half maximum of the X-ray rocking curve of the (002) plane of the first layer. On this occasion, 2θ, ω, χ, and φ were adjusted to set the axis such that a peek assigned to the (002) plane of the first layer was exhibited, and then, determination was carried out within the range of ω=14.5 to 19.5° at an anti-scattering slit of 3 mm. The full width at half maximum of the resulting XRC profile of the (002) plane of the first layer was obtained by peak search after smoothing the profile using XRD analysis software (manufactured by Bruker-AXS, “LEPTOS” Ver. 4.03). Also for the (002) plane of the second layer within a region of 20 to 100 μm away from the second layer surface (that is, the bottom surface of the AlN monocrystalline substrate) in the thickness direction, XRC determination was carried out in the same manner as above to determine the average of the full width at half maximum of the X-ray rocking curve of the (002) plane, and the resulting average was used as the full width at half maximum of the X-ray rocking curve of the (002) plane of the second layer. The ratio of the full width at half maximum of the X-ray rocking curve of the (002) plane of the first layer to the full width at half maximum of the X-ray rocking curve of the (002) plane of the second layer was also determined. The results are shown in Table 1.

The first layer region and the second layer region in the AlN monocrystalline substrate were identified in the following manner. Specifically, XRC determination as described above was carried out at the location every 30 μm away from the surface of the AlN monocrystalline substrate in the thickness direction, and the plane inside the AlN monocrystalline substrate was identified that provided the maximum full width at half maximum of the X-ray rocking curve. Then, the region was regarded as the first layer, the region corresponding to a full width at half maximum of 0.03 to 0.99 times as large as the maximum full width at half maximum of the X-ray rocking curve, wherein the full width at half maximum was 0.005° or more and less than 0.160°; and the other region was regarded as the second layer.

On the other hand, the identification of the first layer and the second layer as described above was impossible in Examples 16 and 17. Accordingly, the full width at half maximum of the X-ray rocking curve of the (002) plane on the top surface of the AlN monocrystalline substrate was used as the full width at half maximum of the X-ray rocking curve of the (002) plane of the first layer, and the full width at half maximum of the X-ray rocking curve of the (002) plane on the bottom surface of the AlN monocrystalline substrate was used as the full width at half maximum of the X-ray rocking curve of the (002) plane of the second layer. Except for these, XRC determination was carried out in the same manner as in Examples 1 to 15. The results are shown in Table 1.

### (2b) Thermal Conductivity

The thermal conductivity of each of the first and second layers in the AlN monocrystalline substrate at 25° C. was calculated using the formula (thermal conductivity)=(heat diffusion coefficient)×(specific heat)×(density). The heat diffusion coefficient of the first layer was obtained by processing the AlN monocrystalline sample into a strip in 5 mm long, 30 mm wide, and 0.2 mm thick from the top surface in the thickness direction and subjecting the strip to determination at 25° C. using an AC method thermal diffusivity measurement system (manufactured by Advanced Technology, Laser PIT-R). The heat diffusion coefficient of the second layer was obtained by processing the AlN monocrystalline sample into a strip in 5 mm long, 30 mm wide, and 0.2 mm thick from the bottom surface in the thickness direction and subjecting the strip to determination at 25° C. using an AC method thermal diffusivity measurement system (manufactured by Advanced Technology, Laser PIT-R). The specific heat of the first layer was obtained by the following manner: the AlN monocrystalline sample was processed into discs each having a diameter of 5 mm and a thickness of 0.2 mm from the top surface in the thickness direction; the discs were stacked to a total thickness of about 1 mm to prepare a sample; and the sample was subjected to the determination at 25° C. using a differential scanning calorimeter (manufactured by NETSCH, DSC 200). The specific heat of the second layer was obtained by the following manner: the AlN monocrystalline sample was processed into discs each having a diameter of 5 mm and a thickness of 0.2 mm from the bottom surface in the thickness direction; the discs were stacked to a total thickness of about 1 mm to prepare a sample; and the sample was subjected to the determination at 25° C. using a differential scanning calorimeter (manufactured by NETSCH, DSC 200). The density of the first layer was obtained by processing the AlN monocrystalline sample into a disc having a diameter of 15 mm and a thickness of 0.2 mm from the top surface in the thickness direction and subjecting the disc sample to determination by Archimedes' method in accordance with JIS R 1634: 1998. The density of the second layer was obtained by processing the AlN monocrystalline sample into a disc having a diameter of 15 mm and a thickness of 0.2 mm from the bottom surface in the thickness direction and subjecting the disc sample to determination by Archimedes' method in accordance with JIS R 1634: 1998. From these, the thermal conductivity of each of the first and second layers were obtained. The ratio of the thermal conductivity of the first layer to the thermal conductivity of the second layer was also determined. The results are shown in Table 1.

### (2c) Defect Density

The defect density of each of the first layer and the second layer of the AlN monocrystalline substrate obtained in Examples 1 to 17 was evaluated by carrying out determination on the whole region of each of the first layer and the second layer using X-ray topography (manufactured by Rigaku Corporation, XRTmicron). In a case where the defect density is 1.0×10⁵/cm² or more, it is difficult to calculate the exact number of etch pits through X-ray topography, and accordingly, evaluation of etch pits by etching with a KOH melting liquid was carried out to determine the defect densities of the first layer and the second layer. The evaluation of etch pits of the first layer was specifically carried out in the following manner: KOH and NaOH were mixed in a weight ratio of KOH:NaOH=1:1 and heated to 450° C. to obtain a melting liquid; the first layer was ground by 30 μm from the surface thereof; the ground surface was immersed in the melting liquid for 5 minutes to etch; and then, the defect density was determined under an optical microscope. This was repeated to evaluate the defect density distribution inside the AlN monocrystalline. The average of the defect densities at the determination points in the first layer was used as the defect density of the first layer. The evaluation of the second layer was carried out in the following manner: KOH and NaOH were mixed in a weight ratio of KOH:NaOH=1:1 and heated to 450° C. to obtain a melting liquid; grinding was started from the surface of the first layer and continued until the remaining thickness of the AlN monocrystalline substrate was 30 μm; the ground surface was immersed in the melting liquid for 5 minutes to etch; and then, the defect density was determined at a plural points under an optical microscope. Thus, the defect density distribution inside the AlN monocrystalline was evaluated. The average of the defect densities at the determination points in the second layer was used as the defect density of the second layer. The ratio of the defect density of the first layer to the defect density of the second layer was also determined. The results are shown in Table 1.

### (2d) Evaluation of Resistance to Cracking

The surface of the AlN monocrystalline substrate ground and polished in (1 b) above was observed under an optical microscope to check whether a crack with a maximum length of 50 μm or more appeared. Ten AlN monocrystalline substrates in total were prepared in the same method as in (1) above, and in these, the number of AlN monocrystalline substrates in which a crack appeared was counted. The rating was conducted on the evaluation criteria shown below. The results are shown in Table 1.

### <Evaluation Criteria>

A: the number of AlN monocrystalline substrates without crack was 9 to 10.
B: the number of AlN monocrystalline substrates without crack was 6 to 8.
C: the number of AlN monocrystalline substrates without crack was 3 to 5.
D: A crack was found in all the AlN monocrystalline substrates.

TABLE 1

| | (002)XRC, full width at half | | | Thermal conductivity | | | Defect density | | | |
|---|---|---|---|---|---|---|---|---|---|---|
| | maximum (°) | | | (W/mK) | | | (×10⁴/cm²) | | | Evaluation of |
| | | | First layer/ | | | First layer/ | | | First layer/ | resistance to |
| | First layer | Second layer | Second layer | First layer | Second layer | Second layer | First layer | Second layer | Second layer | cracking |
| Ex. 1 | 0.007 | 0.16 | 0.04 | 204 | 137 | 1.49 | 5.0 | 114 | 0.04 | A |
| Ex. 2 | 0.014 | 0.16 | 0.09 | 201 | 137 | 1.47 | 10 | 114 | 0.09 | A |
| Ex. 3 | 0.079 | 0.16 | 0.49 | 176 | 137 | 1.28 | 56 | 114 | 0.49 | B |
| Ex. 4 | 0.149 | 0.16 | 0.93 | 150 | 137 | 1.09 | 107 | 114 | 0.94 | C |
| Ex. 5 | 0.007 | 0.09 | 0.08 | 205 | 170 | 1.21 | 4.9 | 64 | 0.08 | A |
| Ex. 6 | 0.014 | 0.09 | 0.16 | 202 | 170 | 1.19 | 10 | 64 | 0.16 | A |
| Ex. 7 | 0.045 | 0.09 | 0.50 | 190 | 170 | 1.12 | 32 | 64 | 0.50 | B |
| Ex. 8 | 0.089 | 0.09 | 0.99 | 173 | 170 | 1.01 | 63 | 64 | 0.98 | C |
| Ex. 9 | 0.007 | 0.04 | 0.18 | 205 | 191 | 1.07 | 4.8 | 29 | 0.17 | A |
| Ex. 10 | 0.014 | 0.04 | 0.35 | 201 | 191 | 1.05 | 9.8 | 29 | 0.34 | B |
| Ex. 11 | 0.019 | 0.04 | 0.48 | 199 | 191 | 1.04 | 14 | 29 | 0.48 | B |
| Ex. 12 | 0.038 | 0.04 | 0.95 | 192 | 191 | 1.00 | 27 | 29 | 0.94 | C |
| Ex. 13 | 0.007 | 0.03 | 0.23 | 206 | 195 | 1.06 | 4.7 | 21 | 0.22 | A |
| Ex. 14 | 0.014 | 0.03 | 0.47 | 203 | 195 | 1.04 | 9.7 | 21 | 0.46 | B |
| Ex. 15 | 0.029 | 0.03 | 0.97 | 195 | 195 | 1.00 | 21 | 21 | 0.98 | C |
| Ex. 16* | 0.007 | 0.007 | 1.00 | 204 | 203 | 1.00 | 5.0 | 5.0 | 1.00 | D |
| Ex. 17* | 0.007 | 0.33 | 0.02 | 200 | 83 | 2.41 | 5 | 236 | 0.02 | A |

*indicates Comparative Example.

What is claimed is:

1. An AlN monocrystalline substrate having a size with a diameter of 5.08 cm (2 inch) or more, wherein the AlN monocrystalline substrate has a two-layer structure composed of a single AlN monocrystalline as a whole, the two-layer structure composed of a first layer and a second layer distinguishable from each other in a thickness direction in terms of a full width at half maximum of an X-ray rocking curve,
wherein a full width at half maximum of an X-ray rocking curve of a (002) plane of the first layer is 0.005° or more and less than 0.160°,
wherein a full width at half maximum of an X-ray rocking curve of a (002) plane of the second layer is 0.03° or more and 0.16° or less, and
wherein a ratio of the full width at half maximum of an X-ray rocking curve of a (002) plane of the first layer to the full width at half maximum of an X-ray rocking curve of a (002) plane of the second layer is 0.03 to 0.99.

2. The AlN monocrystalline substrate according to claim 1, wherein the first layer has a thermal conductivity of 150 to 210 W/mK.

3. The AlN monocrystalline substrate according to claim 1, wherein the second layer has a thermal conductivity of 130 to 200 W/mK.

4. The AlN monocrystalline substrate according to claim 1, wherein a ratio of a thermal conductivity of the first layer to a thermal conductivity of the second layer is 1.00 to 1.50.

5. The AlN monocrystalline substrate according to claim 1, wherein the first layer has a defect density of 4.5×10⁴ to 1.1×10⁶/cm².

6. The AlN monocrystalline substrate according to claim 1, wherein the second layer has a defect density of 2.0×10⁵ to 1.2×10⁶/cm².

7. The AlN monocrystalline substrate according to claim 1, wherein a ratio of a defect density of the first layer to a defect density of the second layer is 0.03 or more and less than 1.00.

8. A device comprising the AlN monocrystalline substrate according to claim 1.
